(19) United States
(12) Patent Application Publication
(10) Pub. No.: US 2007/0285180 A1
(43) Pub. Date: Dec. 13, 2007

(54) WIDE TUNING RANGE AND LOW JITTER VOLTAGE CONTROLLED OSCILLATOR

(76) Inventor: Chien-Hau Wu, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 11/749,164

(22) Filed: May 16, 2007

(30) Foreign Application Priority Data
May 17, 2006 (TW) 095117391

(51) Int. Cl. H03K 3/03

(52) U.S. Cl. 331/57

(57) ABSTRACT

A voltage control oscillator includes a first current source for providing a coarse tune current; a second current source for providing a fine tune current; and a delay line, coupled to the first current source and the second current source, comprising: a first delay cell, coupled to the first current source, for delaying a input clock according to the coarse tune current and outputting a delay clock; and a second delay cell, coupled to the second current source, for delaying the delay clock according to the fine tune current and outputting a output clock; wherein the coarse tune current is used to control the oscillating frequency of the voltage control oscillator close to a target frequency and the fine tune current is used to adjust oscillating frequency of the voltage control oscillator arrive the target frequency.

### CROSS REFERENCE TO RELATED APPLICATION

This application claims the priority benefit of Taiwan Patent Application Serial Number 095117391, filed on May 17, 2006, the full disclosure of which is incorporated herein by reference.

### BACKGROUND OF THE INVENTION

1. Field of the Invention

This invention generally relates to an oscillating signal controller, and more particularly to a voltage controlled oscillator.

2. Description of the Related Art

Please refer to FIG. 1, which shows a Phase Locked Loop (PLL) 100 composed of phase/frequency detector (PFD), charge pump (CP) 104, voltage controlled oscillator (VCO) 106 and divider N 108. As known by the person skilled in the relevant art, all of the delay cells positioned in the VCO 106 is coupled to a same current source as shown in FIG. 2. The input of the voltage controlled current source 202 is coupled to the output of CP 104. The current of the current source 202 is changed with the output voltage of CP 104 controlled by charging and discharging proceeding. Therefore, when the current of the current source 202 changed, the delay time of each delay cell 206 in delay line 204 is changed as well. And that will affect the output frequency of the VCO 106. In general, the oscillating frequency of VCO 106 can be represented by f=½nTd, wherein the n is the number of delay cell and Td is the delay time of one delay cell.

As the schematic diagram shown in FIG. 2, due to all of the delay cells 206 are coupled to the same voltage controlled current source 202, the delay time of each delay cell will be changed when the control voltage Vctrl affected by noise, the current mismatch problem in CP 104 or charge sharing effect in CP 104 to cause the control voltage Vctrl changing. It will generate a larger jitter and phase noise of the VCO 200 and could make the PLL 100 need to re-lock.

### SUMMARY OF THE INVENTION

It is an object of the present invention to provide a wide tuning range and low jitter voltage controlled oscillator by utilizing a coarse tune current and a fine tune current.

In order to achieve the above object, the present invention provides a oscillating signal controller, which comprises a first current source for providing a coarse tune current; a second current source for providing a fine tune current; and a delay line, coupled to the first current source and the second current source, comprising: a first delay cell, coupled to the first current source, for delaying a input clock according to the coarse tune current and outputting a delay clock; and a second delay cell, coupled to the second current source, for delaying the delay clock according to the fine tune current and outputting a output clock; wherein the coarse tune current is used to control the oscillating frequency of the voltage control oscillator close to a target frequency and the fine tune current is used to adjust oscillating frequency of the voltage control oscillator arrive the target frequency.

### BRIEF DESCRIPTION OF THE DRAWINGS

Other objects, advantages, and novel features of the present invention will become more apparent from the following detailed description when taken in conjunction with the accompanying drawings.

FIG. 1 shows a circuit block diagram of a phase locked loop.

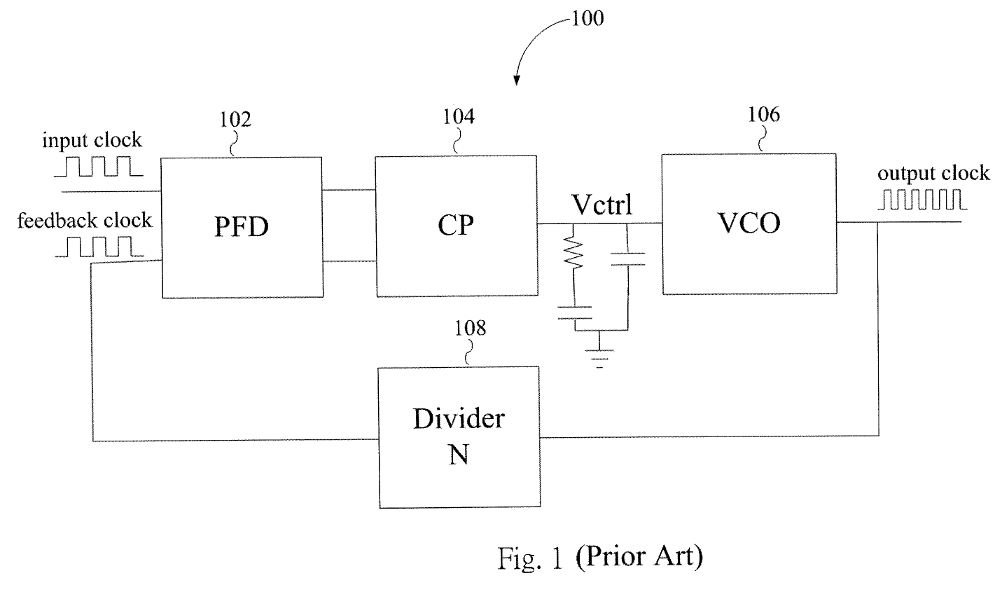

FIG. 2 shows a schematic diagram of a conventional voltage controlled oscillator.

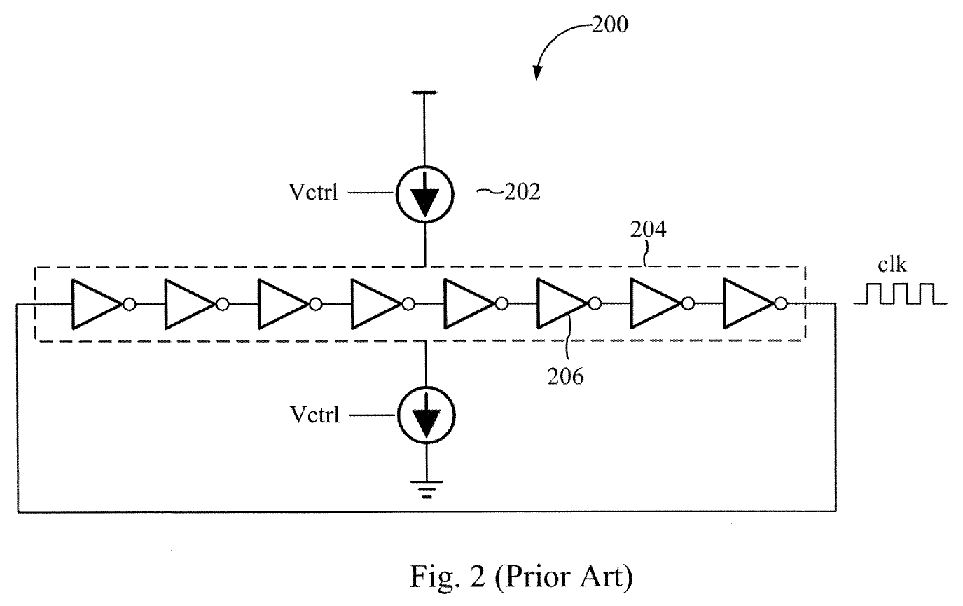

FIG. 3 shows a schematic diagram of a voltage controlled oscillator according to the first embodiment of the present invention.

FIG. 4 shows a schematic diagram of a voltage controlled oscillator according to the second embodiment of the present invention.

FIG. 5 shows a frequency-voltage characteristic curve of the second embodiment of the present invention.

FIG. 6 shows a schematic diagram of a voltage controlled oscillator according to the third embodiment of the present invention.

FIG. 7 shows a frequency-voltage characteristic curve of the third embodiment of the present invention.

FIG. 8 shows an embodiment of a delay cell.

### DETAILED DESCRIPTION OF THE PREFERRED EMBODIMENT

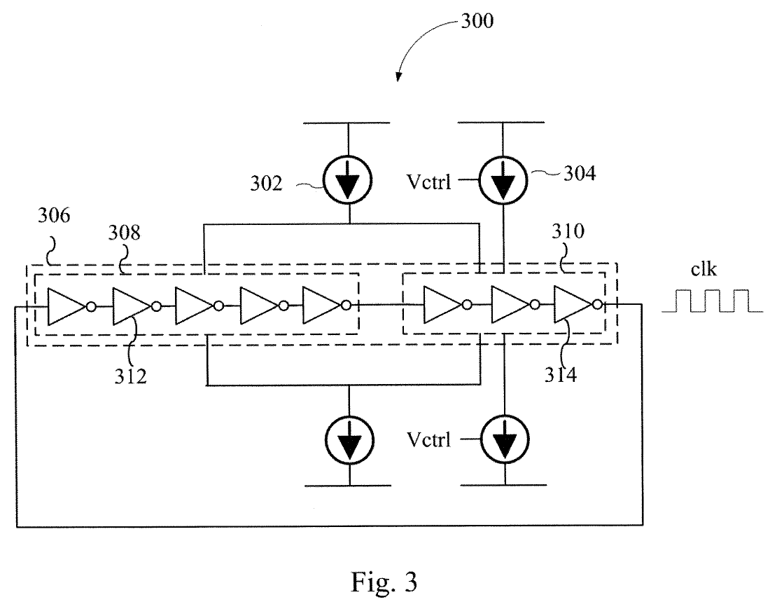

Please refer to FIG. 3, which shows a circuit diagram of a voltage controlled oscillator 300 (VCO) according to the first embodiment of the present invention. The voltage controlled oscillator 300 includes a first current source 302, a second current source 304 and a delay line 306, wherein the first current source 302, the second current source 304 and the delay line 306 constructed as a voltage controlled delay line (VCDL), used to delay the clock signal of the delay line 306 according to the current of the first current source 302, the current of the second current source 304. The delay line 306 includes a first delay line 308 and second delay line 310, wherein the entire delay cells 312 in the first delay line 308 are coupled to the first current source 302, the entire delay cells 314 in the second delay line 314 are coupled to the first current source 302 and the second current source 304. According to the first embodiment of the present invention, the first current source 302 is used to provide a reference current (or coarse current) to generate an initial oscillating frequency, which arriving a reference frequency close to a target frequency within a threshold. In performable embodiment to determine the reference current of first current source 302, a predetermined current value to be the reference current or a frequency detector (not shown) to detector whether the initial output frequency of VCO 300 close to the target frequency within a threshold to further control the first current source could be performed, but not limit. Therefore, when PLL is begging to lock output clock with input clock, it only fine-tune the control voltage Vctrl of the second current source 304 to change the delay time of the second delay line 310 until the output clock and input clock are synchronized. In one embodiment of the present invention, the reference current provided by first current source is larger than the fine-tune current provided by second current source. On the other hand, due to the oscillating frequency of the VCO 300 is ½(N₁×Td₁+N₂×Td₂), wherein N₁ is the first delay cell number in first delay line 308, N₂ is the second delay cell number in second delay line 310, Td₁ is the delay time of one first delay cell, Td₂ is the delay time of one second delay cell, only the second delay line 310 will be affected when control voltage Vctrl is noised, the first delay line 308 will not be affected. Hence, the jitter caused by noise in the VCO 300 is reduced.

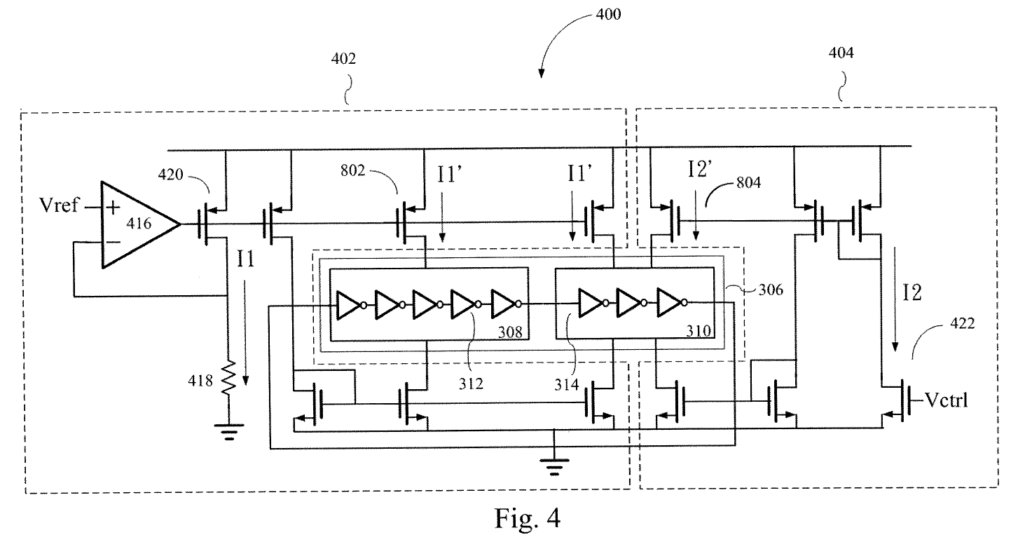

Please refer to FIG. 4, which shows a circuit diagram of a voltage controlled oscillator 400 (VCO) according to the second embodiment of the present invention. The voltage controlled oscillator 400 as fist embodiment includes a first current source 402, a second current source 404 and a delay line 406, wherein the first current source 402, the second current source 404 and the delay line 406 constructed as a voltage controlled delay line (VCDL), used to adjust the delay time of the delay line 406 according to the current of the first current source 402, the current of the second current source 404. In the second embodiment, the first current source 402 further includes an operational amplifier 416, a reference resistor 418 and a transistor 420, wherein the reference resistor 418 receiving a reference voltage Vref to generate a reference current I1, and further generate the first current I1′ to the first delay line 408 and the second delay line 410 by current mirror circuit. And the first current I1′ can be determined and designed by adjusting reference voltage Vref, reference resistor 418 or aspect ratio of current mirror circuit, etc. On the other hand, the reference resistor 418 can be set in the chip or out of the chip according to the design requirement. The second current source 404 further includes a transistor 422 receiving the control voltage Vctrl outputted by charge pump to generate the current I2, and a current mirror circuit for mirroring the current I2 and outputting current I2′ to the second delay line 410, hereby controls the delay time of the second delay line 410.

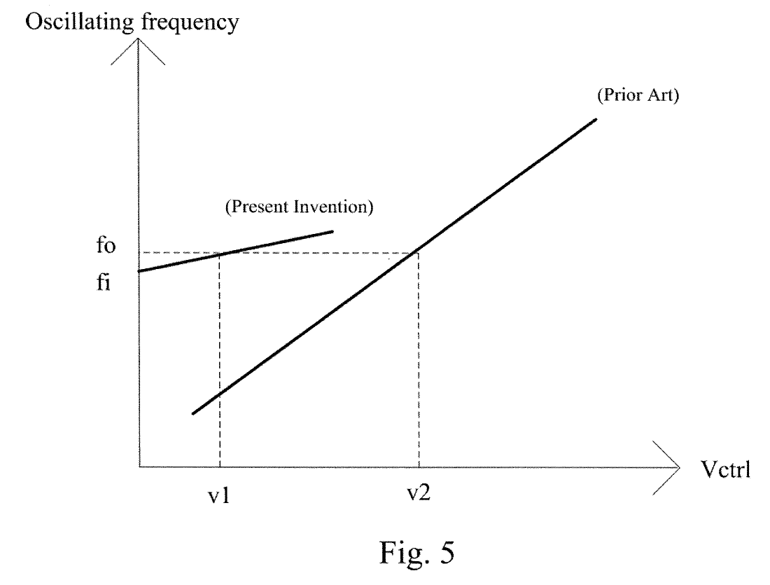

Please refer to FIG. 5, which shows the frequency-voltage characteristic curve of the VCO 400. X-axis represents the control voltage Vctrl, Y-axis represents the output frequency of VCO 400. As shown in FIG. 5, it is clear that the gain value of the present invention is small than the gain value of the prior art, and which will cause little jitter than prior art when control voltage Vctrl is affected by noise. On the other hand, VCO 400 can generate an initial oscillating frequency fi close to target frequency fo when VCO 400 is under initial situation (Vctrl=0), and that will get the advantage of reducing the settling time of PLL.

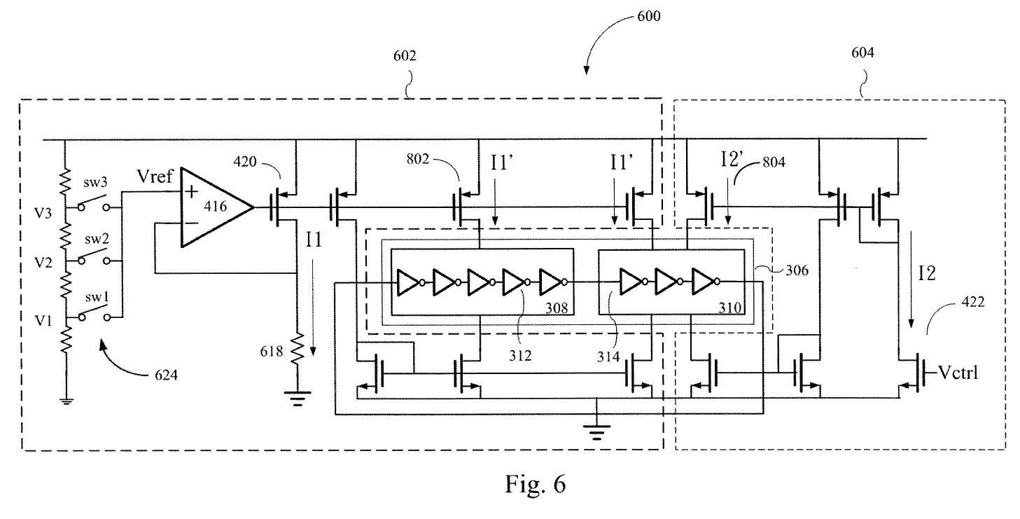

Please refer to FIG. 6, which shows a circuit diagram of a voltage controlled oscillator 600 (VCO) according to the third embodiment of the present invention. The difference between third embodiment and second embodiment is that reference voltage Vref in first current source 602 is variable to hereby construct a wide tuning range VCO 600. In the third embodiment, VCO 600 can first coarse tune the first current I1′ by adjusting the reference voltage Vref through switch 624 (sw1, sw2, sw3) until the initial oscillating frequency is close to target frequency. And accordingly fine tune the second current I2′ by adjusting the control voltage Vctrl until PLL is locked. In this embodiment, it could perform a frequency detector (not shown) to detect whether the output frequency of VCO 600 is close to target frequency or central frequency, and decides a voltage (V1, V2, V3) to be the reference voltage Vref according to the detected result. On the other hand, an alternative embodiment of the present invention could be performed, that is, utilizing a variable resistor to be the resistor 618. Similarly, in the initial state, the output frequency of VCO 600 can rapidly close to target frequency by adjusting the variable resistor 618 to further coarse tune the first current I1′. And it could also perform a frequency detector to detect the output frequency and determine the resistance value of the variable resistor 618 according to the detected result.

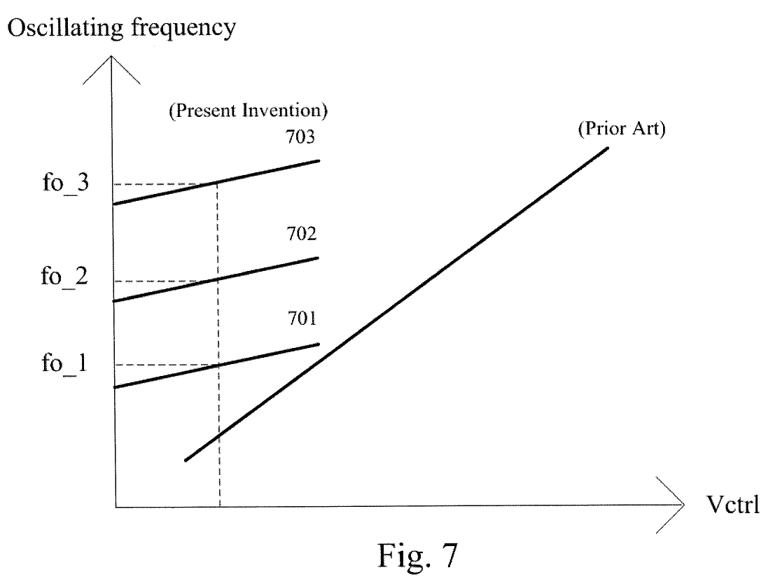

Please refer to FIG. 7, which shows the frequency-voltage characteristic curve of the VCO 600. X-axis represents the control voltage Vctrl, Y-axis represents the output frequency of VCO 600. As shown in FIG. 7, VCO 600 has larger tuning range (f0_1, fo_2, fo_3) than VCO 400, and also with the characteristic of low jitter. The characteristic curves (701, 702, 703) are corresponding to the reference voltage Vref (or resistance of variable resistor 618). Therefore, a larger reference voltage Vref (or smaller resistance of variable resistor 618) is selected to generate a larger current I1′ when required frequency of PLL is higher. Contrarily, a smaller reference voltage Vref (or larger resistance of variable resistor 618) is selected to generate a smaller current I1′ when required frequency of PLL is lower. On the other hand, the adjustable tuning range architecture VCO 600 also can overcome the process variation by properly selecting a suitable reference voltage Vref or resistance of resistor 618 to get a desired central frequency.

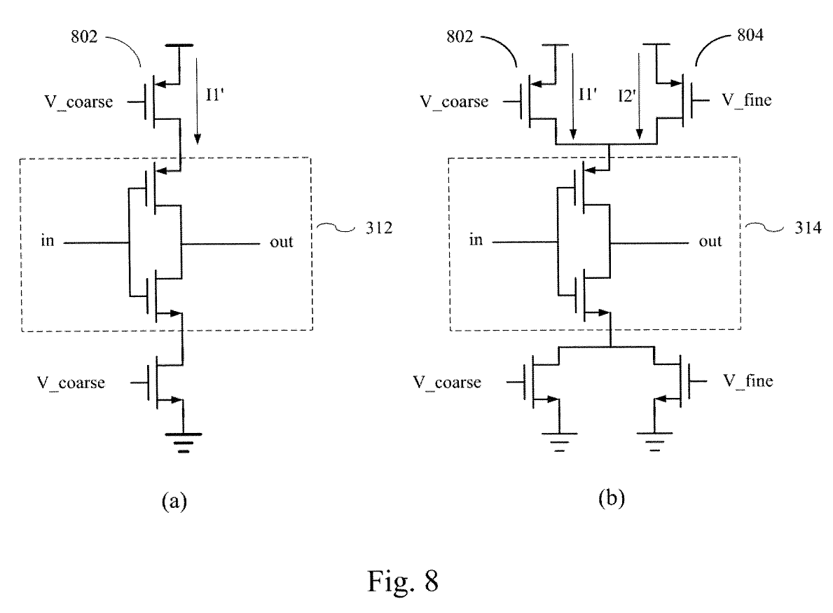

Please refer to FIG. 8, which shows the embodiment of delay cell in delay line, FIG. 8(a) is the first delay cell in first delay line 308, FIG. 8(b) is the second delay cell in second delay line 310. The timing delay of delay cell shown in FIG. 8(a) is determined by the current I1′ of transistor 802, which is controlled by the coarse tune voltage V_coarse. The difference between first delay cell shown in FIG. 8(a) and second delay cell shown in FIG. 8(b) is that second delay cell further includes a transistor 804 controlled by fine tune voltage V_fine for providing a fine tune current I2′ to control the timing delay. On the other hand, the delay cell shown in FIG. 8(a) and FIG. 8(b) is a kind of single-end delay cell, but utilizing differential-end delay cell (not shown) in the present invention is also performable.

Although the present invention, voltage controlled oscillator controlled by a coarse tune current and a fine tune current, uses PLL to be an application embodiment, but the person ordinary skilled in the relevant arts clearly know that the present invention also could used in a voltage control delay line (VCDL) positioned in delay locked loop (DLL). Furthermore, in the aforementioned embodiment, the first current source 302 is electronically coupled to the first delay line 308 and the second delay line 310, but it is also being performed when the first current source 302 is only coupled to the first delay line 308 without coupled to second delay line 310.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. An oscillating signal controller, comprising:
a first current source for providing a first current;
a second current source for providing a second current; and
a delay line, coupled to the first current source and the second current source, comprising:
a first delay cell, coupled to the first current source, for delaying a input oscillating signal according to the first current and outputting a delay oscillating signal; and
a second delay cell, coupled to the second current source, for delaying the delay oscillating signal according to the second current and outputting a output oscillating signal;
wherein the first current controls the oscillating frequency of the output oscillating signal to arrive a reference frequency close to a target frequency within a threshold; and the second current controls the oscillating frequency of the output oscillating signal to arrive a target frequency.

2. The oscillating signal controller as claimed in claim 1, further comprising:
a frequency detector, for detecting the oscillating frequency of the output oscillating signal and controlling the first current source so as to perform the oscillating frequency of the output oscillating signal to arrive the reference frequency close to the target frequency within the threshold.

3. The oscillating signal controller as claimed in claim 1, wherein the second delay cell further coupled to first current source for receiving the first current.

4. The oscillating signal controller as claimed in claim 1, wherein the first current source comprises:
a resistor, for generating a reference current according to a reference voltage; and
a current mirror, for mirroring the reference current to generate the first current.

5. The oscillating signal controller as claimed in claim 4, further comprising:
a switch unit, receiving a plurality of input reference voltage, for selecting at least one of the input reference voltages to determine the reference voltage.

6. The oscillating signal controller as claimed in claim 4, wherein the resistor is a variable resistor.

7. The oscillating signal controller as claimed in claim 1, wherein the second current is corresponding to the output voltage of a charge pump.

8. The oscillating signal controller as claimed in claim 1, is a voltage controlled oscillator (VCO).

9. The oscillating signal controller as claimed in claim 1, wherein the first delay cell and the second delay cell are single-end delay cell or differential-end delay cell.

10. The oscillating signal controller as claimed in claim 1, is positioned in a phase locked loop (PLL).

11. A oscillating signal controller, comprising:
a first current source for providing a coarse tune current;
a second current source for providing a fine tune current; and
a delay line, coupled to the first current source and the second current source, comprising:
a first delay cell, coupled to the first current source, for delaying a input oscillating signal according to the coarse tune current and outputting a delay oscillating signal; and
a second delay cell, coupled to the second current source, for delaying the delay oscillating signal according to the fine tune current and outputting a output oscillating signal;
wherein the coarse tune current and the fine tune current are different.

12. The oscillating signal controller as claimed in claim 11, wherein the second delay cell further coupled to first current source for receiving the coarse tune current.

13. The oscillating signal controller as claimed in claim 11, wherein the first current source comprises:
a resistor, for generating a reference current according to a reference voltage; and
a current mirror, for mirroring the reference current to generate the coarse tune current.

14. The oscillating signal controller as claimed in claim 13, further comprising:
a switch unit, receiving a plurality of input reference voltage, for selecting at least one of the input reference voltages to determine the reference voltage.

15. The oscillating signal controller as claimed in claim 13, wherein the resistor is a variable resistor.

16. The oscillating signal controller as claimed in claim 11, wherein the fine tune current is corresponding to the output voltage of a charge pump.

17. The oscillating signal controller as claimed in claim 11, is a voltage controlled oscillator (VCO).

18. The oscillating signal controller as claimed in claim 11, wherein the first delay cell and the second delay cell are single-end delay cell or differential-end delay cell.

19. The oscillating signal controller as claimed in claim 11, is positioned in a phase locked loop (PLL).

20. The oscillating signal controller as claimed in claim 11, is positioned in a delay locked loop (DLL).
